(19) United States
(12) Patent Application Publication
(10) Pub. No.: US 2013/0247979 A1
(43) Pub. Date: Sep. 26, 2013

(54) NEW ELECTRICAL CONDUCTOR FOR ATTACHING SILICON WAFERS IN PHOTOVOLTAIC MODULES

(71) Applicants: Tag Hammam, Sundbyberg (SE); Bevis Hutchinson, Kista (SE); Lena Ryde, Kista (SE)

(72) Inventors: Tag Hammam, Sundbyberg (SE); Bevis Hutchinson, Kista (SE); Lena Ryde, Kista (SE)

(73) Assignee: LUVATA ESPOO OY, Espoo (FI)

(21) Appl. No.: 13/990,478

(22) PCT Filed: Nov. 30, 2010
(86) PCT No.: PCT/EP2010/068496

§ 371 Date: May 30, 2013

(51) Int. Cl. H01B 1/02; C22F 1/08; H01L 31/02

(52) U.S. Cl. CPC H01B 1/026; H01L 31/02008; C22F 1/08
USPC 136/256; 174/126.1; 148/684; 228/123.1

(57) ABSTRACT

The invention relates to an electrical conductor (2) having a longitudinal axis (A) parallel to the rolling direction of a conductor wire, comprising copper material and an attachment surface (7) configured for attaching to a receiving surface of a silicon wafer (3) to establish an electrical connection. The copper material has a purity of at least 99.5% wherein the grains have a cubic texture comprising a set of cubic axes directed within an up to 20 degree angular range to the longitudinal axis (A), and whereby at least 65% of the grains have said cubic texture. The invention also relates to a process for manufacturing conductor (2) and photo voltaic modules comprising said conductor (2), and silicon wafers.

### THE FIELD OF THE INVENTION

The present invention refers to an elongated electrical conductor according to the characterized portion of claim 1 and a process for manufacturing an electrical conductor according the characterized portion of claim 10 as well as a photovoltaic module comprising said conductor attached to a silicon wafer.

### BACKGROUND OF THE INVENTION AND PRIOR ART

A crystalline silicon photovoltaic module consists in general of a number of silicon wafers or solar cells connected in series. The series connection is made from the front of the first silicon wafer to the back of the next silicon wafer and so forth. The electrical connections between the silicon wafers are made by soldering two or three copper string-wires on each side of the silicon wafers. There is a significant risk of bowing of the skin silicon wafers during the soldering process or afterwards due to the fact that the string is stretched during cooling. This happens because the coefficient of thermal expansion is significantly higher for copper than for silicon. The bowing is associated with tensile stresses in the thin and brittle silicon wafer and results in a high frequency of cell breakage. Cracks may also be initiated at the edge of the wafers just under the string-wire due to the intense mechanical stress.

It is desired to reduce the thickness of the silicon wafers to reduce the electrical losses. Furthermore, traditional tin-lead solder is desired to be replaced with lead-free tin, which will result in increased soldering temperature. These factors act to increase the mechanical stress in the silicon wafer. Moreover, at the same time, there is a need to maintain the present wafer size, as well as the design of the metallisation pattern and the general concept of the string-wires. Altogether, this means that the mechanical properties of the string-wire become a very important issue since they have a direct impact on the mechanical stress that arises in the silicon wafer during the soldering process.

WO2009/049572 discloses an improved cable connection comprising an elastic design for an electrical conductor for silicon wafers in plate-shaped solar modules. This design however does not solve the problem of breaking and cracking of the silicon wafers due to soldering.

U.S. Pat. No. 7,173,188 describes an improved electrical conductor which is coated to prevent wrapping of the conductor during soldering. US200910017325 describes rolled copper foil with improved flexible fatigue properties, which is made in a 5 step process resulting in copper with crystal grains having a cubic texture. This is however a material for use in high strength products.

There is still a need for improved copper material that can reduce the risk for fracture in the silicon wafers.

### SUMMARY OF THE INVENTION

The object of the present invention is to provide improved string-wires wherein the stress in the copper material in the electrical conductor is minimised to prevent the load on the silicon wafers from becoming large enough to cause damage to the wafers.

The object is achieved by the electrical conductor initially defined characterized in that the copper material is present at a purity of at least 99.5% and wherein the grains have a cubic texture comprising a set of cubic axes directed within an up to 20 degree angular range to the longitudinal axis, and whereby at least 65% of the grains have said cubic texture.

The advantage of this copper material is that it ensures that the stress in the copper string-wires is as minimised as possible so that the load on the silicon wafers is as small as possible. This stress level is determined by the mechanical properties of the string-wire, which are susceptible to control by tailoring the crystallographic texture and microstructure of the copper material.

The purity of the copper is important for the mechanical properties of the electrical conductor. In one embodiment the copper material has a purity of at least 99.9%.

Beside the orientation of the grains in the cubic texture, it is also important that most of the copper material has the cubic texture. In one embodiment 70 to 100% of the grains have the cubic texture.

To minimise the mechanical stress in the copper material, the orientation of the grains in the cubic texture is important. In another embodiment the set of cubic axes are directed within a 15 degree angular range to the longitudinal axis. In a further embodiment the set of cubic axes are directed within a 10 degree angular range to the longitudinal axis.

The sharpness or strength of the copper texture is important with regard to the resulting anisotropy of mechanical properties. It is necessary that a sufficient proportions of grains (crystals) in the copper sheet/wire are correctly orientated with respect to the sheet axes. An important criterion in this regard is the degree of coincidence between the longitudinal axis of the string wire and the cube axes of the copper crystals. The cube axes are referred to as <100> directions in the standard crystallographic Miller index notation. Optimising the material requires a high degree of coincidence between <100> directions in the grains and the longitudinal axis of the sheet/wire. The texture strength is best described by a cube axis index (CA index), which is defined as the volume percentage of the copper that is orientated such that the angle between the longitudinal axis and <100> is less than 15 degrees. In one embodiment the cube axis index is at least 70%. For comparison, copper material having no specific texture (i.e. randomly orientated) may have a CA index below 15%.

Preferably, the copper material is an Electrolytic Tough Pitch copper or an Oxygen-Free copper.

For a given level of (thermal) strain, the stress in the string-wire may depend on two factors, namely the elastic modulus (Young's modulus, E) and the yield stress (Rp) of the copper material. The Young modulus is controlled only by the crystallographic texture, while the yield stress depends on both the texture and the microstructure (the grain structure). In one embodiment the copper material has a yield stress below 50 MPa.

A strong cubic texture may reduce the elastic stress level in the string-wire up to 45%, as compared to similar material without cubic texture. In one embodiment the copper material has a Young modulus below 95 GPa.

The object of the invention is also achieved by a process for manufacturing an electrical conductor comprising a copper material at a purity of at least 99.5% characterized in that the process comprises the steps of:
a) arranging the copper material to a rolling mill,
b) rolling the copper material along a rolling direction to a reduction from 20 to 80%, wherein a copper product is formed,
c) annealing the copper product at a temperature below 600° C.,
d) optionally repeating steps b) and c),
e) cold rolling the copper product to a reduction of at least 80%, and
f) final annealing the copper product at a temperature above 250° C.

As discussed above, the properties of the copper material are important to minimise the mechanical stress in the copper material. Therefore, in one embodiment the process is preferably performed with copper material that has a purity of at least 99.9%. In another embodiment the grain size of the copper material after steps b) and c) is from 5 to 25 μm. In a further embodiment the copper material is an Electrolytic Tough Pitch copper or an Oxygen-Free copper.

To optimise the mechanical properties of the copper material obtained by the process described above even further, some of the process parameters can be changed. In another embodiment the reduction in step b) is from 30 to 80%. In a further embodiment the temperature in step c) is from 300 to 400° C. In yet another embodiment the reduction in step d) is from 90 to 99%. In one embodiment the temperature in step f) is above 500° C.

The object of the present invention is also achieved by an electrical conductor manufactured by the process described above.

In one embodiment the attachment surface of the electrical conductor is coated with tin based solder material.

The invention further relates to a process for attaching the electrical conductor to a silicon wafer, characterized in that the attachment surface of the electrical conductor and the receiving surface of the silicon wafer are heated to melt the solder material, whereby an attachment is formed between the electrical conductor and the silicon wafer upon cooling of the heated material.

One embodiment of the invention relates to a photovoltaic module comprising at least one silicon wafer attached to at least one electrical conductor.

### BRIEF DESCRIPTION OF THE DRAWINGS

The invention will now be explained more closely by means of a description of various embodiments and with reference to the drawings attached hereto.

FIG. 1. A schematic photovoltaic module comprising a series of silicon wafers connected by electrical conductors.

FIG. 2. A schematic view of the receiving surface of a silicon wafer and the attachment surface of an electrical conductor.

FIG. 3. A flow scheme of the manufacturing process.

### DETAILED DESCRIPTION OF VARIOUS EMBODIMENTS OF THE INVENTION

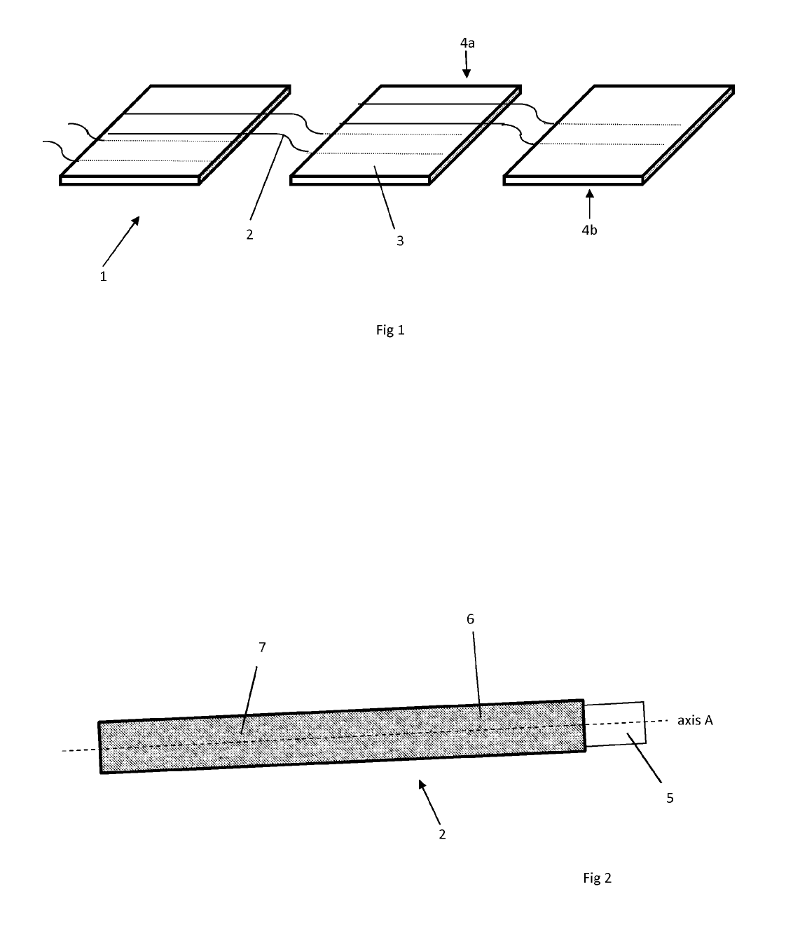

FIG. 1 shows an example of a photovoltaic module 1 containing at least one silicon wafer 3 attached to at least one electrical conductor 2. Normally, the photovoltaic module 1 comprises a series of silicon wafers 3 connected to each other by electrical conductors 2, whereby one silicon wafer 3 is attached to at least two, or at least four electrical conductors 2.

FIG. 2 shows the improved electrical conductor 2 for use in a photovoltaic module or crystalline silicon photovoltaic module 1. The electrical conductor 2 comprises a conductor core 5 consisting of a copper material and a coating of tin based solder material 6. The coating preferably comprises a tin based lead-free solder material 6, but other solder material 6 may be used.

In general, the whole conductor core 5 of the electrical conducfor 2 is coated with the coating 6. For purpose of presenting the structure of the electrical conductor 2, the conductor core 5 of a right part of the electrical conductor 2 has been exposed in FIG. 2. The conductor core 5 may have a rectangular cross-section. Through this rectangular cross-section the electrical conductor 2 forms a flat surface adapted to be attached to an upper and/or lower surfaces 4a, 4b of the silicon wafer 3.

The solder material 6 forms an attachment surface 7 adapted to be positioned in contact with the upper or lower surface 4a, 4b of the silicon wafer 3. Referring to FIG. 1, the attachment surface 7 is adapted to be positioned in contact with the receiving surface on the upper surface 4a of a first silicon wafer 3 (the electrical conductor 2 being marked with a solid line) and with the receiving surface on the lower surface 4b of an adjacent second silicon wafer 3 (the electrical conductor 2 being marked with a doted line). The upper surface 4a and the lower surface 4b are positioned on opposite sides of the first and second silicon wafer 3.

The electrical conductor 2 is attached to the silicon wafer 3 by positioning the conductor 2 in contact with the receiving surface on the upper surface 4a of the first silicon wafer 3 and the receiving surface on the lower surface 4b of the adjacent second silicon wafer 3, and heating the first and the second silicon wafer 3 together with the electrical conductor 2, thereby melting the solder material 6. Hereby, an attachment is formed between the electrical conductor 2 and the silicon wafers 3 upon cooling of the heated material.

Because of the heat used during soldering and because the silicon wafers 3 are fragile, it is important to use a conductor core 5 material of the electrical conductor 2 that prevents damaging the silicon wafer 3.

A low yield strength of the conductor core 5 material in the direction of a longitudinal axis A of the conductor core 5 is desired in order to mitigate the mechanical stress in the silicon wafers 3. Such stesses occur due to difference in thermal conductivity between the material of the silicon wafers 3 and the material of the electrical conductor 2.

The conductor core 5 comprises of copper material that has a purity of at least 99.5%. The purity may also be 99.6%, or 99.7%, or 99.8%, or 99.9%. The amount of impurities in the copper material is preferably less than 0.5%.

The copper material may be any copper material available on the market. Preferably, the copper material is an Electrolytic Tough Pitch copper or an Oxygen-Free copper.

The mechanical properties improve by the number of grains that have the cubic texture. Preferably, at least 70%, or 75% of the grains in the copper material of the electrical conductor have the cubic texture. The copper material may have from 80 to 100%, or 80 to 90%, or 90 to 99.9%, or 95 to 99.9% of the grains in the cubic texture.

The longitudinal axis A of the conductor core 5 is essentially parallel to the rolling direction of a conductor wire. Furthermore, the copper material of the conductor core 5 comprises of grains which are orientated in a cubic texture comprising a first set of cubic axes directed to the longitudinal axis A and other sets of cubic axes that are directed essentially perpendicular to the longitudinal axis A. The angle of the first set of axes may deviate from the longitudinal axis A. This symmetrical deviation is pefeably less than ±30 degrees relative to the longitudinal axis A. The first set of cubic axes may be directed within a range up to 25 degrees to the longitudinal axis A. This set of cubic axes may also be directed within a range up to 20, or up to 15, or up to 10, or up to 5 degrees to the longitudinal axis A.

For the sake of clarity, the electrical conductor 2 of the present invention may comprise any combination of ranges and intervals mentioned above for any of the purity of the copper material, range of degrees to the longitudinal axis A and amount of grains that have the cubic texture. For example, the copper material may comprise of 99.95% pure copper, a set of cubic axes directed within the range up to 12 degrees to the longitudinal axis A and from 80 to 100% of the grains in the cubic texture or any other value that falls within the ranges and intervals mentioned above.

Assessment of the texture of the copper material in the string-wire of the electrical conductor 2 can be made using conventional techniques such as X-ray diffraction and electron backscattering diffraction (EBSD). The mechanical properties of the material that can be measured are for example the yield stress or strength and the Young modulus. The Taylor factor may be evaluated from measurements of the texture.

The electrical conductor 2 of the present invention preferably comprises copper material that has a yield stress below 50, or 45, or 40 MPa. The yield stress in the string-wire of the electrical conductor 2 is preferably reduced by at least 10%, or 20%, or 30%, or more as compared to similar material without cubic texture. The Young modulus is preferably below 95, or 80, or 70 GPa.

The cubic orientation also conveys advantages in reducing the yield stress of the string-wire. A strong cubic texture may reduce the yield stress level in the string-wire by 20%, or 40%, or more as compared to similar material without cubic texture. This can be definied in terms of the so called Taylor factor (M) for plastic flow. M is lower for metals that have a cubic texture compared to metals without the cubic texture. In another embodiment the copper material has a Taylor factor of 3, or below 2.75, or less.

The copper material comprised in the electrical conductor 2 may be manufactured using different processes. However, control of material and process parameters are important to obtain the preferred strong cubic texture.

The copper material used in the process preferably has a purity of at least 99.5%. The purity may also be at least 99.6%, or 99.7%, or 99.8%, or 99.9%. The amount of impurities in the copper material is preferably less than 0.5%.

The copper material used in the process described above is may be Electrolytic Tough Pitch copper or Oxygen-Free copper.

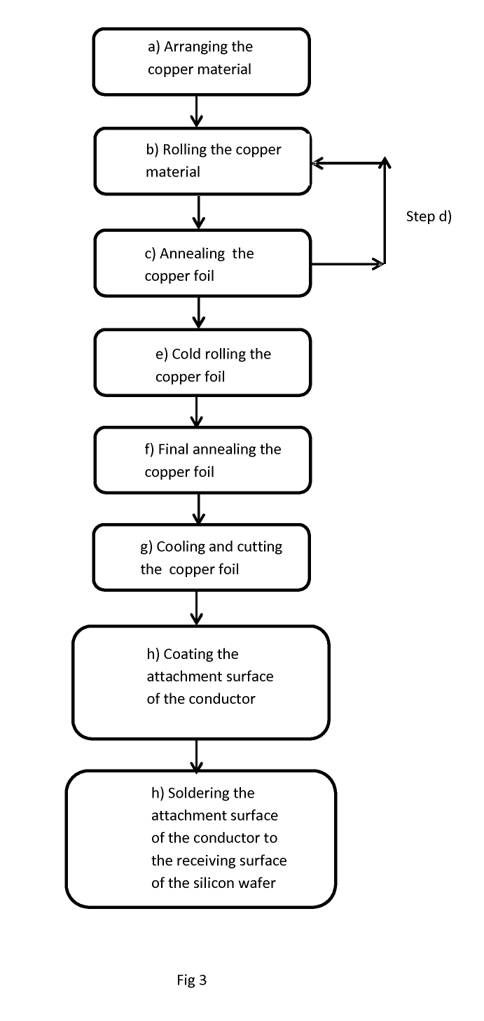

FIG. 3 shows a flow chart for the manufacturing process. The process starts by arranging the copper material to a rolling mill in step a). Next, in step b), the copper material is rolled along a rolling direction to reduce the copper material to form a product such as for example a strip, a sheet or a flat wire. This reduction may be from 20 to 90%, or 20 to 80%, or 20 to 70%, or 30 to 90%, or 30 to 80%, or 30 to 70%. The rolling in step b) may be performed cold or hot or at an intermediate cold temperature up to 150° C., preferably at a temperature below 125° C., or 100° C., or 75° C. In step c) the copper product is annealed at a temperature below 600° C., or 500° C., or 400° C. The temperature may be in the range from 300 to 400° C. In one embodiment the temperature is 350° C.

The microstructure of the copper is preferably a fine grain size whereby the grain size after steps b) and c) does not exceed 30 μm. Preferably, the grain size is below 25 μm, or 20 μm, or 15 μm or from 2 to 25 μm, or 5 to 20 μm, or 5 to 15 μm, or 2 to 10 μm. Steps b) and c) may be repeated one, two, or more times if necessary.

Annealing step c) is followed by cold rolling the product in step e) to reduce the product at least 80%, or 90%, or 95%, or 98%, or from 90 to 99%, or 95 to 99%, or 98 to 99%. Final annealing of the product is done in step f). The temperature in step f) is preferably above 250° C., or 400° C., or 500° C., or 600° C.

The cubic texture in the copper material obtained by the process described above is orientated such that the first set of cubic axes are directed essentially to the rolling direction of the copper product as used in the manufacturing process of the product (i.e. the longitudinal axis A). The other sets of cubic axes are directed essentially perpendicular to the rolling direction of the copper product.

For the sake of clarity, the process may be conducted with any combination of ranges and intervals mentioned above for any of the purity of the copper material, grain size, temperature and reductions. For example, the process may be conducted with copper material comprising 99.9% pure copper, with a reduction in step b) from 30 to 80% at an intermediate level of cold (below 150° C.), the annealing step c) may be done at 350° C., resulting in a grain size below 26 μm and the reduction in step d) may be in the range from 90 to 98%, and the temperature in step f) may be above 500° C.

The terms ‘essentially’ as used herein shall be interpreted in the broadest sense, including all or almost all, or 99%, 95%, 90%, 85%, 80%, or 75% of all.

The present invention is not limited to the embodiments disclosed but may be varied and modified within the scope of the following claims.

1. An elongated electrical conductor (2) having a longitudinal axis (A) essentially parallel to the rolling direction of a conductor wire, which conductor (2) comprises of copper material, an attachment surface (7) configured to be attached to a receiving surface of a silicon wafer (3) to establish an electrical connection between the silicon wafer (3) and the electrical conductor (2), characterized in that the copper material is present at a purity of at least 99.5%, and wherein the grains have a cubic texture comprising a set of cubic axes directed within an up to 20 degree angular range to the longitudinal axis (A), and whereby at least 65% of the grains have said cubic texture.

2. The electrical conductor (2) according to claim 1, characterized in that the copper material has a purity of at least 99.9%.

3. The electrical conductor (2) according to claim 1, characterized in that 70 to 100% of the grains have the cubic texture.

4. The electrical conductor (2) according to claim 1, characterized in that the set of cubic axes are directed within a 15 degree angular range to the longitudinal axis (A).

5. The electrical conductor (2) according to claim 1, characterized in that the set of cubic axes are directed within a 10 degree angular range to the longitudinal axis (A).

6. The electrical conductor (2) according to claim 1, characterized in that the cubic axis index is at least 70%.

7. The electrical conductor (2) according to claim 1, characterized in that the copper material is an Electrolytic Tough Pitch copper or an Oxygen-Free copper.

8. The electrical conductor (2) according to claim 1, characterized in that the copper material has a yield stress below 50 MPa.

9. The electrical conductor (2) according to claim 1, characterized in that the copper material has a Young modulus below 95 GPa.

10. A process for the manufacturing of an electrical conductor (2), comprising a copper material at a purity of at least 99.5%, characterized in that the process comprises the steps of:
a) arranging the copper material to a rolling mill,
b) rolling the copper material along a rolling direction to a reduction from 20 to 80%, wherein a copper product is formed,
c) annealing the copper product at a temperature below 600° C.,
d) optionally repeating the steps b) and c),
e) cold rolling the copper product to a reduction of at least 80%, and
f) final annealing the copper product at a temperature above 250° C.

11. The process according to claim 10, characterized in that the copper material has a purity of at least 99.9%.

12. The process according to claim 10, characterized in that the grain size of the copper product after steps b) and c) is 5 to 25 μm.

13. The process according to claim 10, characterized in that the copper material is an Electrolytic Tough Pitch copper or an Oxygen-Free copper.

14. The process according to claim 10, characterized in that the reduction in step b) is from 30 to 80%.

15. The process according to claim 10, characterized in that the temperature in step c) is from 300 to 400° C.

16. The process according to claim 10, characterized in that the reduction in step d) is from 90 to 99%.

17. The process according to claim 10, characterized in that the temperature in step 0 is above 500° C.

18. An electrical conductor (2) manufactured by the process according to claim 10.

19. The electrical conductor (2) according to claim 18, characterized in that the attachment surface (7) is coated with tin based solder material (6).

20. A process for attaching the electrical conductor (2) according to claim 19 to a silicon wafer (3), characterized in that the attachment surface (7) of the electrical conductor (2) and the receiving surface of the silicon wafer (3) are heated to melt the solder material (6), whereby an attachment is formed between the electrical conductor (2) and the silicon wafer (3) upon cooling of the heated material.

21. A photovoltaic module (1) comprising at least one silicon wafer (3) attached to at least one electrical conductor (2) according to claim 19.

22. The elongated electrical conductor (2) according to claim 1, characterized in that the attachment surface (7) is coated with tin based solder material (6).
